(19) United States
(12) Patent Application Publication
(10) Pub. No.: US 2014/0132344 A1
(43) Pub. Date: May 15, 2014

(54) Broadband Doherty Amplifier Using Broadband Transformer

(71) Applicant: Noureddine Outaleb, Nepean (CA)

(72) Inventor: Noureddine Outaleb, Nepean (CA)

(73) Assignee: ROCKSTAR CONSORTIUM US LP, Plano, TX (US)

(21) Appl. No.: 14/131,155

(22) PCT Filed: Jul. 13, 2011
(86) PCT No.: PCT/CA2011/000799

§ 371 Date: Jan. 6, 2014

(51) Int. Cl. H03F 3/68; H03F 3/189

(52) U.S. Cl. CPC H03F 3/68; H03F 3/189
USPC 330/124 R

(57) ABSTRACT

A radio frequency amplification unit is provided. The radio frequency amplification unit comprises a main amplifier, wherein the main amplifier is operable to amplify a first portion of an input signal, an auxiliary amplifier, wherein the auxiliary amplifier is operable to turn on and to amplify a second portion of the input signal when the amplitude of the second portion of the input signal fourth signal exceeds a threshold amplitude, and a broadband impedance transformer that is coupled between an output of the main amplifier and an output of the auxiliary amplifier. The broadband impedance transformer produces an transformed output of the main amplifier based on an output of the main amplifier. The broadband impedance transformer comprises a quarter wavelength matching line coupled to a directional coupler, wherein the directional coupler has the same electrical length as the quarter wavelength matching line.

### CROSS-REFERENCE TO RELATED APPLICATIONS

This application is a filing under 35 U.S.C. 371 of International Application No. PCT/CA2011/000799 filed Jul. 13, 2011, entitled “Broadband Doherty Amplifier Using Broadband Transformer,” which application is incorporated by reference herein in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Power amplifiers may be employed in a variety of electronics applications, including wireless communications. Generally speaking, power amplifiers amplify an input electrical signal to produce an output electrical signal that has increased amplitude relative to the input. Base transceiver stations, enhanced nodes B, and/or cell sites may incorporate one or more radio frequency power amplifiers to boost the power of a signal prior to emitting from an antenna and/or antenna array. Portable electronic devices likewise may incorporate power amplifiers to boost the power of a signal prior to emitting from an antenna. The Doherty amplifier architecture has become widely used as a power amplifier in some wireless communication applications. While the Doherty amplifier may be implemented in a variety different structures, generally the Doherty amplifier comprises a main amplifier and an auxiliary amplifier (also known as a carrier amplifier and a peak amplifier, respectively). The auxiliary amplifier is biased Class-C and thus remains OFF for the low input signal envelope of the Doherty amplifier, and the output of the Doherty amplifier is then provided by the output of the main amplifier alone. The auxiliary amplifier turns ON when the input drive signal of the Doherty amplifier is at or above an amplitude threshold, and the output of the Doherty amplifier is then provided by the combination of the outputs of both the main amplifier and the auxiliary amplifier.

### SUMMARY

In an embodiment, a radio frequency amplification unit is disclosed. The radio frequency amplification unit comprises a main amplifier, wherein the main amplifier is operable to amplify a first portion of an input signal, an auxiliary amplifier, wherein the auxiliary amplifier is operable to turn on and to amplify a second portion of the input signal when the amplitude of the second portion of the input signal exceeds a threshold amplitude, and a broadband impedance transformer that is coupled between the main amplifier and an output of the auxiliary amplifier. The broadband impedance transformer produces a transformed output of the main amplifier based on an output of the main amplifier. The broadband impedance transformer produces the transformed output of the main amplifier based on an output of the main amplifier, wherein the broadband impedance transformer comprises a quarter wavelength matching line coupled to a directional coupler, wherein the directional coupler has the same electrical length as the quarter wavelength matching line.

In an embodiment, a radio frequency power amplifier is disclosed. The radio frequency power amplifier comprises a signal splitter that splits an input radio frequency signal into a first signal and a second signal, a first amplifier that amplifiers the first signal to form a third signal, a second amplifier that amplifies the second signal to form a fourth signal, and a broadband impedance transformer that transforms the third signal to a fifth signal. The broadband impedance transformer comprises a quarter wavelength matching line coupled to a directional coupler, wherein the directional coupler has the same electrical length as the quarter wavelength matching line.

In an embodiment, a radio frequency power amplifier is disclosed. The radio frequency power amplifier comprises a signal splitter that splits an input radio frequency signal into a first signal and a second signal, a first amplifier that amplifiers the first signal to form a third signal, a second amplifier that amplifies the second signal to form a fourth signal, and a broadband impedance transformer that transforms the third signal to a fifth signal. The broadband impedance transformer comprises a quarter wavelength matching line coupled to a directional coupler, wherein the directional coupler has the same electrical length as the quarter wavelength matching line and wherein the directional coupler is a broadside-coupled line coupler.

In an embodiment, a method of amplifying a radio frequency signal is disclosed. The method comprises splitting an input radio frequency signal into a first signal and a second signal, amplifying the first signal to form a third signal, amplifying the second signal to form a fourth signal, and transforming the third signal to a fifth signal with a broadband impedance transformer. The broadband impedance transformer comprises a quarter wavelength matching line coupled to a directional coupler, wherein the directional coupler has the same electrical length as the quarter wavelength matching line.

These and other features will be more clearly understood from the following detailed description taken in conjunction with the accompanying drawings and claims.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is an illustration of a wireless communication system according to an embodiment of the disclosure.

FIG. 2 is an illustration of a power amplifier according to an embodiment of the disclosure.

FIG. 3 is an illustration of a broadband transformer according to an embodiment of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

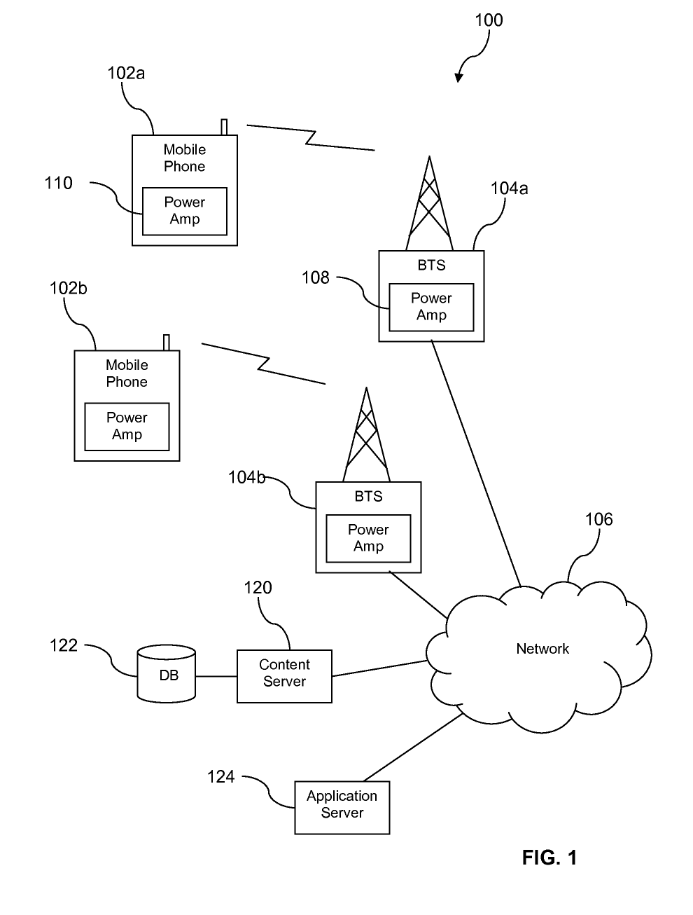

Turning now to FIG. 1, a wireless communication system 100 is described. The system 100 comprises mobile phones 102, base transceiver stations 104, and network 106. A first mobile phone 102a may communicate with a second mobile phone 102b, for example carry on a voice conversation, via the base transceiver stations 104 and the network 106. A first base transceiver station 104a provides a wireless communication link to the first mobile phone 102a and couples it to the network 106. A second base transceiver station 104b provides a wireless communication link to the second mobile phone 102b and couples it to the network 106. The network 106 may be any combination of one or more public networks and/or one or more private networks. Once coupled to the network 106 via the base transceiver station 104, the mobile phone 102 may access content via the content server 120 and content data store 122 and/or access network services via application server 124.

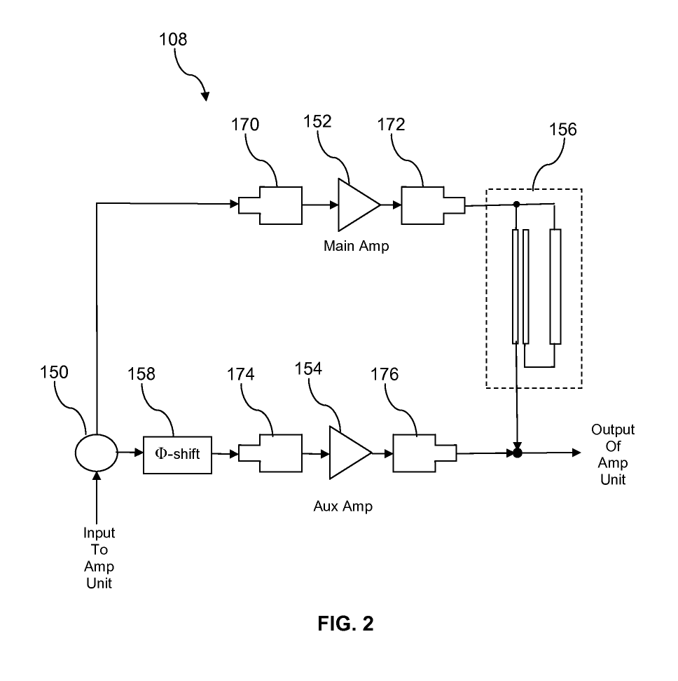

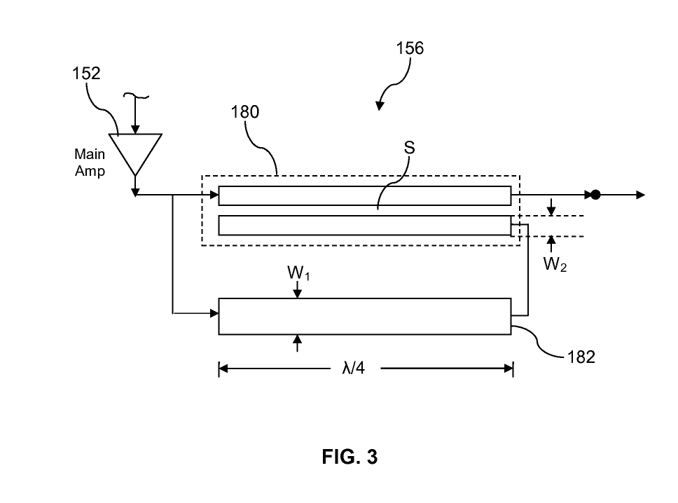

The base transceiver station 104 may provide wireless communication links using any of a variety of wireless communication protocols for example, but not by way of limitation, code division multiple access (CDMA), global system for mobile communications (GSM), long-term evolution (LTE), worldwide interoperability for microwave access (WiMAX), or other wireless communication protocol. In some contexts the base transceiver station 104 may be referred to as an enhanced node B or a cell tower or some other term. As used herein, the base transceiver station 104 and/or cell tower is understood to comprise an antenna and a BTS power amplifier (108). The mobile phone 102 comprises a mobile power amplifier 110. In an embodiment, the power amplifiers 108, 110 boost output power levels of the base transceiver station 104 and the mobile phone 102, respectively, to a level that promotes an acceptable quality wireless communication link. It is understood that the mobile power amplifier 110 may share many of the features of the power amplifier 108 described in further detail below with respect to FIG. 2 and FIG. 3. While the description of FIG. 1 is based on a mobile phone 102, it is understood that other portable electronic devices, for example personal digital assistants (PDAs), media players, air interface cards embedded in or coupled to laptop computers or other portable computers may likewise feature a power amplifier 110 and engage in wireless communications with the network 106 via a wireless link provided by the base transceiver station 104.

Turning now to FIG. 2, details of the power amplifier 108 are discussed in more detail. In an embodiment, the power amplifier 108 comprises a signal splitter 150, a main amplifier 152, an auxiliary amplifier 154, a broadband transformer 156, and a phase shifter 158. A signal may be input to the signal splitter 150, a first portion of the input signal may be conveyed to the main amplifier 152 and a second portion of the input signal may be conveyed to the phase shifter 158. The phase shifter 158 provides a phase shift to the second portion of the input signal such that the output of the broadband transformer 156 combines in-phase with the output of the auxiliary amplifier 154. The power amplifier 108 may be implemented as a power amplifier printed circuit board. The power amplifier 108 may be referred to in some contexts as a radio frequency power amplifier. In some embodiments, the power amplifier 108 is consistent with a Doherty-type amplifier architecture.

In an embodiment, the main amplifier 152 may be provided with input biasing and output biasing to achieve a desirable operating point, as would be understood by one skilled in the art. In an embodiment, the power amplifier 108 may comprise a main amplifier input matching network 170 and a main amplifier output matching network 172. It is expressly understood that the main amplifier output matching network 172 is different and distinct from the broadband transformer 156.

In an embodiment, the auxiliary amplifier 154 may be provided with input biasing and output biasing to achieve a desirable operating point, as would be understood by one skilled in the art. In an embodiment, the auxiliary amplifier 154 is biased such that the auxiliary amplifier 154 only turns ON and amplifies when the second portion of the input signal exceeds a threshold amplitude. In an embodiment, the auxiliary amplifier 154 is biased for Class C operation.

In an embodiment, the signal splitter 150 may split an input signal equally such that the first portion of the input signal may be substantially equal to the second portion of the input signal. In an alternative embodiment, however, the signal splitter 150 may split the input signal according to a different ratio. Alternatively, in an embodiment, the auxiliary amplifier 154 may be biased for Class B operation, and the signal splitter 150 may perform input signal shaping. For example, the signal splitter 150 may provide a constant fraction of the input signal as the first portion of the input signal to the main amplifier 152 but may provide the second portion of the input signal to the auxiliary amplifier 154 only when the input signal exceeds a threshold value. This kind of input conditioning may be referred to as input signal shaping and can be used to adapt out some of the undesirable effects that may be experienced when the auxiliary amplifier 154 is transitioning between a fully OFF state to a fully ON state and between the fully ON state to the fully OFF state. For further details about signal shaping, see U.S. patent application Ser. No. 12/482,110 filed Jun. 10, 2009, entitled “Doherty Amplifier and Method for Operation Thereof,” by Gregory J. Bowles, et al., which is incorporated by reference herein in its entirety.

In an embodiment, the phase shifter 158 introduces a quarter-wavelength (90 degree) phase shift into the second portion of the input signal, but in other embodiments the phase shifter 158 may introduce a different phase shift. For example, in an embodiment, of the power amplifier 108 wherein an output transistor of the main amplifier 152 and an output transistor of the auxiliary amplifier 154 are formed of different materials and/or of different semiconductor families from each other, the phase shift created by the phase shifter 158 may be different from a quarter-wavelength. The fabrication and use of power amplification units having an output transistor of a main amplifier formed of a first material having a first material composition and belonging to a first semiconductor family and having an output transistor of an auxiliary amplifier formed of a second material having a second material composition and belonging to a second semiconductor family, wherein at least one of the first material composition is different from the second material composition and the first semiconductor family is different from the second semiconductor family, is described in detail in U.S. Pat. No. 7,541,866 filed Sep. 29, 2006, issued Jun. 2, 2009, entitled “Enhanced Doherty Amplifier with Asymmetrical Semiconductors,” by Gregory Bowles, et al., which is incorporated by reference herein in its entirety.

In an embodiment, the power amplifier 108 comprises linearization circuitry to improve the performance of the power amplifier 108. For example, an output of the power amplifier 108 is sensed, the difference between an input to the power amplifier and the output of the power amplifier is determined, one or more predistortion values is determined and stored, and the predistortion values are employed by circuitry (not shown) of the power amplifier 108 to offset and/or compensate for uncorrected non-linearities of the power amplifier 108. For further details about using predistortion to linearize a power amplifier, see U.S. Pat. No. 6,275,685, field Dec. 10, 1998, issued Aug. 14, 2001, entitled “Linear Amplifier Arrangement,” by David N. Wessel, et al., which is incorporated by reference herein in its entirety. It is understood that the present disclosure is consistent with and contemplates other methods or determining, storing, and providing predistortion and/or other methods for linearizing the power amplifier 108.

The broadband transformer 156 provides a radio frequency impedance match to an output, for example to an antenna, such that the output of the main amplifier 152 is radiated rather than reflected back into the main amplifier 152. It happens that the broadband transformer 156 introduces a phase shift into the signal output by the main amplifier 152. In an embodiment, the broadband transformer 156 introduces an about quarter-wavelength phase shift in the output of the main amplifier 152.

The broadband transformer 156 has been analyzed to be a limiting factor of the frequency bandwidth of the power amplifier 108. The power amplifier 108 featuring the broadband transformer 156 may be used interchangeably in a number of different wireless protocols. This may promote reduced engineering design and test costs. For example, the power amplifier 108 may be designed once, tested once, and then deployed without further alternation in either a first spectrum band or a second spectrum band, where the first and second spectrum bands are widely separated. An exemplary design of the power amplifier 108 has been analyzed to provide a theoretical 75% bandwidth: a bandwidth with a center frequency of about 2 GHz and a bandwidth of about 1.4 GHz to about 2.6 GHz. In an embodiment, the broadside transformer 156 under some operating circumstances may provide a 1:4 impedance transformation. In an embodiment, the broadband transformer 156 may provide an about 12.5 Ohm to about 50 Ohm impedance transformation under some operating circumstances. In an embodiment, under another operating circumstance, the broadband transformer 156 may provide an about 25 Ohm to 100 Ohm impedance transformation.

Turning now to FIG. 3, details of the broadband transformer 156 are described. The broadband transformer 156 comprises a directional coupler 180 and a quarter wavelength matching line 182. The quarter wavelength matching line 182 has an electrical length that is approximately equal to a quarter wavelength at the designed center frequency of the power amplifier 108. It is understood that the power amplifier 108 may be operated in a frequency bandwidth whose center frequency is offset from the design center frequency of the power amplifier.

The directional coupler 180 comprises two substantially parallel planar metal traces, each trace having substantially the same electrical length as the quarter wavelength matching line 182. In an embodiment, the quarter wavelength matching line 182 and one of the two metal traces of the directional coupler 180 are positioned in the same plane of a circuit board structure embodying the power amplifier 108. The quarter wavelength matching line 182 may be implemented as a metal trace having width W₁. The two traces of the directional coupler 180 may be desirably fabricated as a broadside-coupled line coupler, using either microstrip technology or stripline technology. In another embodiment, however, the directional coupler 180 may not be implemented using a broadside-coupled line architecture but a different coupling architecture. The directional coupler 180 may have a coupling factor of about 3 dB to about 5 dB. The metal traces of the quarter wavelength matching line 182 and or the directional coupler 180 can be implemented as a copper core coated with gold, silver, or other metal.

The spacing between the two traces of the directional coupler 180 is S and the width of both of the two traces of the directional coupler 180 is W₂. In an embodiment, W₁ may have a value in the range 36 mil to 40 mil, W₂ may have a value in the range 15 mil to 18 mil, and S may have a value in the range 10 mil to 14 mil. The dielectric material associated with the directional coupler 180 may have a permittivity εᵣ in the range from 2.0 to 2.5. In an embodiment, the substrate of the directional coupler 180 may comprise FR4 type substrate material. In an embodiment, the thickness or height of the dielectric in which the directional coupler is embedded may be about 55 mil to 70 mil. It is understood that other dimensions of the structures comprising the broadband transformer 156 are also contemplated by the present disclosure.

The present disclosure further teaches a method of amplifying a radio frequency signal. The method comprises splitting an input radio frequency signal into a first signal and a second signal, amplifying the first signal to form a third signal, and amplifying the second signal to form a fourth signal. The method further comprises transforming the third signal to a fifth signal with a broadband impedance transformer. The impedance transformer comprises a quarter wavelength matching line coupled to a directional coupler, wherein the directional coupler has the same electrical length as the quarter wavelength matching line. The method may be practiced with the power amplifier 108 described above with reference to FIG. 2 and the broadband transformer 156 described above with reference to FIG. 3. In an embodiment, the method further comprises shifting the phase of the second signal by an amount to compensate for a phase shift introduced by the broadband impedance transformer, before the second signal is provided to the second amplifier, for example before providing the second signal to the auxiliary amplifier 154 of FIG. 2. The method may comprise superpositioning the fifth signal and the fourth signal to form a radio frequency output, for example for transmitting over an antenna. The fifth signal and the fourth signal may be superpositioned by an electrical junction, for example by a combination node.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

1. A radio frequency amplification unit, comprising:
a main amplifier, wherein the main amplifier is operable to amplify a first portion of an input signal;
an auxiliary amplifier, wherein the auxiliary amplifier is operable to turn on and to amplify a second portion of the input signal when the amplitude of the second portion of the input signal exceeds a threshold amplitude; and
a broadband impedance transformer that is coupled between an output of the main amplifier and an output of the auxiliary amplifier, that produces a transformed output of the main amplifier based on an output of the main amplifier, wherein the broadband impedance transformer comprises a quarter wavelength matching line coupled to a directional coupler, wherein the directional coupler has the same electrical length as the quarter wavelength matching line.

2. The radio frequency amplification unit of claim 1, wherein the directional coupler has a coupling factor of about 3 dB to about 5 dB.

3. The radio frequency amplification unit of claim 1, wherein the directional coupler is a broadside-coupled line coupler.

4. The radio frequency amplification unit of claim 1, wherein the directional coupler is built using stripline technology.

5. The radio frequency amplification unit of claim 1, wherein the directional coupler is built using microstrip technology.

6. The radio frequency amplification unit of claim 1, wherein the quarter wavelength matching line has a width in a range of 36 mil to 40 mil, wherein the directional coupler is a broadside-coupled line coupler, wherein the lines of the directional coupler each have a width in the range of 15 mil to 18 mil, and wherein the lines of the directional coupler are separated by a space in the range of 10 mil to 14 mil.

7. A radio frequency power amplifier, comprising:
a signal splitter that splits an input radio frequency signal into a first signal and a second signal;
a first amplifier that amplifies the first signal to form a third signal;
a second amplifier that amplifies the second signal to form a fourth signal; and
a broadband impedance transformer that transforms the third signal to a fifth signal, wherein the broadband impedance transformer comprises a quarter wavelength matching line coupled to a directional coupler, wherein the directional coupler has the same electrical length as the quarter wavelength matching line.

8. The radio frequency power amplifier of claim 7, wherein the radio frequency power amplifier is a base transceiver station power amplifier.

9. The radio frequency power amplifier of claim 7, wherein the radio frequency power amplifier is a mobile phone power amplifier.

10. The radio frequency power amplifier of claim 7, wherein the broadband impedance transformer is an about 1:4 impedance transformer.

11. The radio frequency power amplifier of claim 7, wherein the broadband impedance transformer is an about 12.5 ohm to about 50 ohm impedance transformer.

12. The radio frequency power amplifier of claim 7, wherein the radio frequency power amplifier is implemented as a power amplifier printed circuit board.

13. The radio frequency power amplifier of claim 7, wherein the radio frequency power amplifier is a Doherty-type amplifier.

14. The radio frequency power amplifier of claim 7, wherein the radio frequency power amplifier has a center frequency of about 2 GHz and a bandwidth of about 1.4 GHz to about 2.6 GHz.

15. A method of amplifying a radio frequency signal, comprising:
splitting an input radio frequency signal into a first signal and a second signal;
amplifying the first signal to form a third signal;
amplifying the second signal to form a fourth signal; and
transforming the third signal to a fifth signal with a broadband impedance transformer, wherein the broadband impedance transformer comprises a quarter wavelength matching line coupled to a directional coupler, wherein the directional coupler has the same electrical length as the quarter wavelength matching line.

16. The method of claim 15, wherein the quarter wavelength matching line and the directional coupler are formed of copper coated with one of gold and silver.

17. The method of claim 15, wherein a main amplifier amplifies the first signal, wherein an auxiliary amplifier amplifies the second signal, and wherein the main amplifier and the auxiliary amplifier are part of a Doherty-type amplifier.

18. The method of claim 15, further comprising shifting the phase of the second signal by an amount to compensate for a phase shift introduced by the broadband impedance transformer, before the second signal is provided to the second amplifier.

19. The method of claim 15, wherein the directional coupler is a broadside-coupled line coupler.

20. The method of claim 15, wherein the directional coupler is built using one of microstrip technology and stripline technology.
